(19) United States
(12) Patent Application Publication
(10) Pub. No.: US 2009/0278526 A1
(43) Pub. Date: Nov. 12, 2009

(54) CURRENT DETECTING DEVICE

(75) Inventor: Tadafumi Yoshida, Nissin-shi (JP)

Correspondence Address: GIFFORD, KRASS, SPRINKLE,ANDERSON & CITKOWSKI, P.C, PO BOX 7021, TROY, MI, 48007-7021, US

(73) Assignee: Toyota Jidosha Kabushiki Kaisha, Aichi-Ken (JP)

(21) Appl. No.: 12/427,307

(22) Filed: Apr. 21, 2009

(30) Foreign Application Priority Data
May 7, 2008 (JP) 2008-121089

(51) Int. Cl. G01R 19/00; G01R 33/07

(52) U.S. Cl. 324/117 H

(57) ABSTRACT

A current detecting device is provided having a plurality of Hall elements, a board on which the Hall elements are surface-mounted, and a core which surrounds a pass-through section through which a bus bar, through which a current to be detected flows, is passed and which has, at a part of the core, an opening in which the Hall element is placed, wherein the plurality of Hall elements are placed in series along a direction of a magnetic field line formed in the opening when a current flows through the bus bar. With such a structure, a core size of the current detecting device which uses the Hall element is reduced.

### CROSS-REFERENCE TO RELATED APPLICATION

This application claims priority to Japanese Patent Application No. 2008-121089, filed on May 7, 2008.

### BACKGROUND OF THE INVENTION

1. Field of the Invention

The present invention relates to a current detecting device which takes advantage of the Hall effect.

2. Description of the Related Art

In electronic components equipped in a vehicle, a current detecting device in which a core, which passes a magnetic field, and a Hall element are combined is used.

A current detecting device having a structure in which a Hall element and a sensor board are stored in a resin case to which a core is molded is known. In this current detecting device, as shown in an assembly diagram of FIG. 6, two Hall elements 10a and 10b are mounted on one side of a sensor board 12. A core 14, on the other hand, is formed with a tubular magnetic material having an opening 14a which is partially cut out along an axial direction A. Both of the Hall elements 10a and 10b are inserted in the opening 14a of the core 14 side by side and along the axial direction A, to form a current detecting device.

Another current detecting device is known in which, as shown in an assembly cross sectional diagram of FIG. 7 and in a plan view of FIG. 8, two Hall elements 16a and 16b are mounted at positions opposing each other with a sensor board 18 therebetween, the sensor board 18 is sandwiched by the cores 20 and 22 which are partially cut out along an axial direction B to define openings 20a and 22a, respectively, and which are each made of a tubular magnetic material, and both the Hall elements 16a and 16b are inserted into the openings 20a and 22a of the cores 20 and 22, side by side and along the axial direction B of the cores 20 and 22.

In the above-described current detecting devices of the related art, because two Hall elements are placed side by side along the axial direction of the core, there is a problem in that the thickness in the axial direction is increased in the core as a whole. As a result, the cost of the material is increased, and moreover, the size of the current detecting device is increased.

### SUMMARY OF THE INVENTION

According to one aspect of the present invention, there is provided a current detecting device comprising a plurality of Hall elements, a board on which the Hall elements are surface-mounted, and a core which surrounds a pass-through section through which a bus bar, through which a current to be detected flows, is passed, and which has, at a part of the core, an opening in which the Hall element is placed, wherein the plurality of Hall elements are placed in series along a direction of a magnetic field line formed in the opening when a current flows through the bus bar.

### BRIEF DESCRIPTION OF THE DRAWINGS

An exemplary embodiment of the present invention will be described in detail based on the following figures, wherein:

FIG. 1 is an assembly diagram showing a structure of a current detecting device according to a preferred embodiment of the present invention;

FIG. 2 is a diagram showing a state of mounting of a Hall element in a preferred embodiment of the present invention;

FIG. 3 is a plan view showing an internal structure of a current detecting device in a preferred embodiment of the present invention;

FIG. 4 is a diagram showing an assembly state of a current detecting device in a preferred embodiment of the present invention;

FIG. 5 is a diagram showing an internal structure of a current detecting device in an alternative embodiment of the present invention;

FIG. 6 is an assembly diagram showing a structure of a current detecting device of related art;

FIG. 7 is an assembly cross sectional diagram showing an internal structure of a current detecting device of related art; and

FIG. 8 is a plan view showing an internal structure of a current detecting device of related art.

### DESCRIPTION OF THE PREFERRED EMBODIMENT

### Preferred Embodiment

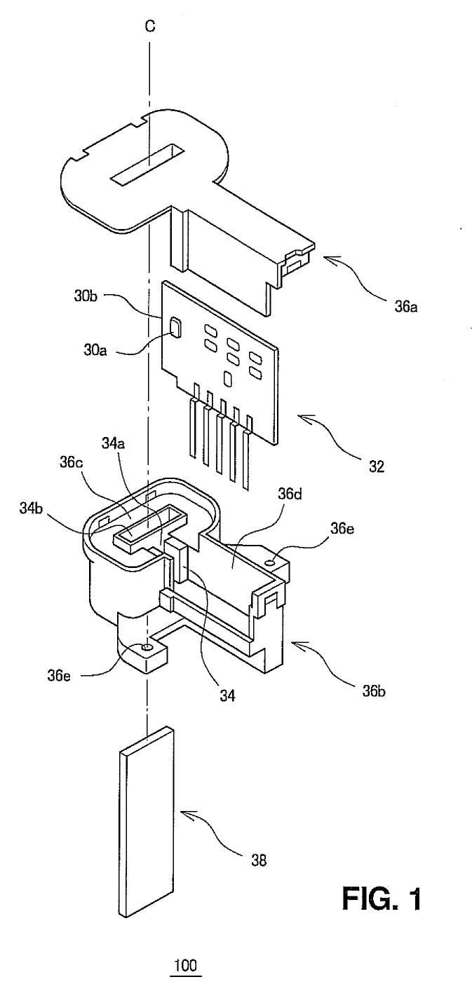

As shown in an assembly diagram of FIG. 1, a current detecting device 100 of a preferred embodiment of the present invention comprises Hall elements 30a and 30b, a sensor board 32, a core 34, core cases 36a and 36b, and a bus bar 38.

The Hall elements 30a and 30b are magnetic sensors which take advantage of the Hall effect, and are elements which convert a change of a magnetic field through the core 34 due to a change of current flowing through the bus bar 38 into an electric signal and output the electric signal.

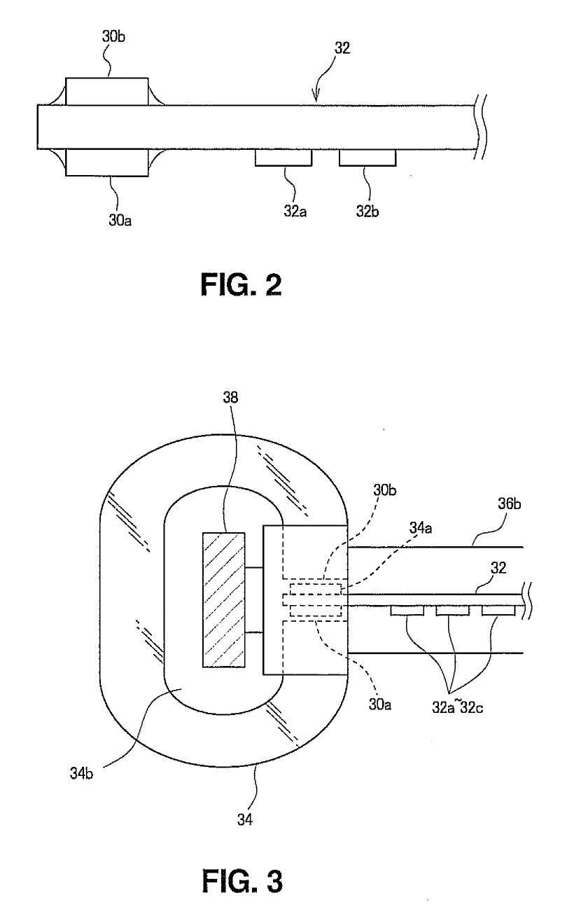

The sensor board 32 may be a printed board in which lines are patterned on a resin such as polyimide. As shown in a side view of FIG. 2, the Hall elements 30a and 30b are mounted on the sensor board 32, opposing each other with an end of the sensor board 32 therebetween. In addition, amplifier circuit elements 32a, 32b, etc. which amplify the voltages output from the Hall elements 30a and 30b are mounted on the sensor board 32. The Hall elements 30a and 30b are surface-mounted on a front surface and a back surface of the sensor board 32 with reflow soldering or the like, and output terminals are connected to input terminals of the amplifier circuit elements 32a and 32b, respectively.

The core 34 is formed with a magnetic structure such as ferrite, a silicon steel plate, a layered steel plate in which metal such as permalloy is layered, etc. Preferably, the surface of the core 34 is coated with a resin as necessary.

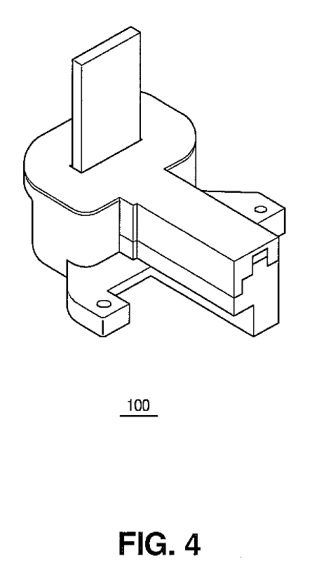

The core 34 is formed in a tubular shape with an opening 34a which is cut out from an upper surface to a lower surface along an axial direction C. As shown in an internal plan view of FIG. 3, the opening 34a is formed slightly larger than a thickness of a layered portion of the Hall elements 30a and 30b and the sensor board 32.

An outer periphery of the core 34 is formed slightly smaller than an outer tubular section of a double hollow portion of a core storage 36c of a core case 36b. In addition, the hollow section of the core 34 forms a pass-through section 34b through which the bus bar 38 is passed. The pass-through section 34b is formed slightly larger than an inner tubular section of the double hollow portion of the core storage 36c of the core case 36b.

The core case 36a is combined with the core case 36b, to store, in the inside, the sensor board 32 on which the Hall elements 30a and 30b are mounted and the core 34. The core case 36b includes the core storage 36c which stores the core 34 and which has the double hollow tubular shape, and a board storage 36d which stores the sensor board 32 provided to protrude from a location at which the opening 34a is positioned when the core 34 is stored in the core storage 36c.

An attachment hole 36e for fixing the current detecting device 100 on a control board or the like may be formed on the core case 36b.

The bus bar 38 is a conductor through which the current to be detected flows. The bus bar 38 is extended from, for example, a power element (power module) to be mounted on the vehicle. The bus bar 38 is inserted to the pass-through section 34b of the core 34 stored in the core storage 36c, in the axial direction C.

When the bus bar 38 is passed through the core cases 36a and 36b having the sensor board 32 on which the Hall elements 30a and 30b are mounted and the core 34, the current detecting device 100 is formed as shown in the assembly diagram of FIG. 4.

In the current detecting device 100, the Hall elements 30a and 30b mounted on both surfaces of the sensor board 32 are inserted into the opening 34a of the core 34 along the axial direction C. With this structure, the change of the magnetic flux through the core 34 due to the change of the current flowing through the bus bar 38 can be converted and obtained using each of the hall elements 30a and 30b.

In addition, in the current detecting device 100, by mounting the Hall elements 30a and 30b on both surfaces of the sensor board 32, even if the core 34 is provided covering the entirety of the Hall elements 30a and 30b, it is possible to reduce the thickness of the core 34 compared to that of the current detecting device of the related art. In other words, the size of the core 34 can be reduced while maintaining the precision of detection at the same level as that of the current detecting device of the related art.

With such a configuration, the manufacturing cost of the current detecting device can be reduced. In addition, the size of the current detecting device can be reduced.

With the provision of the two Hall elements 30a and 30b, it is possible to improve the precision and reliability of the current detection by the current detecting device 100. For example, the detected voltages of the Hall elements 30a and 30b can be compared with each other, to check the precision of the detected voltages. Moreover, even when one of the Hall elements 30a and 30b fails, the other Hall element can be used for detection.

### Alternative Embodiment

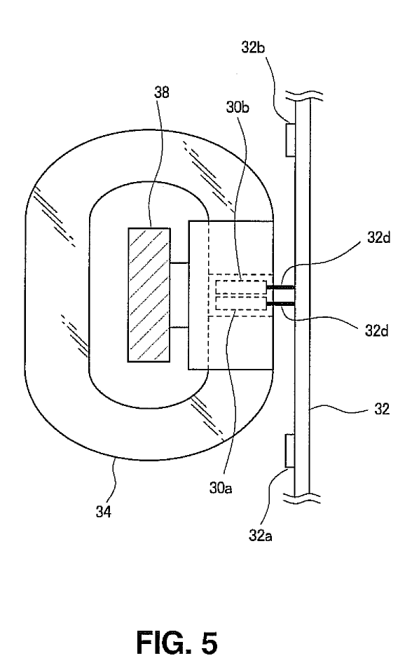

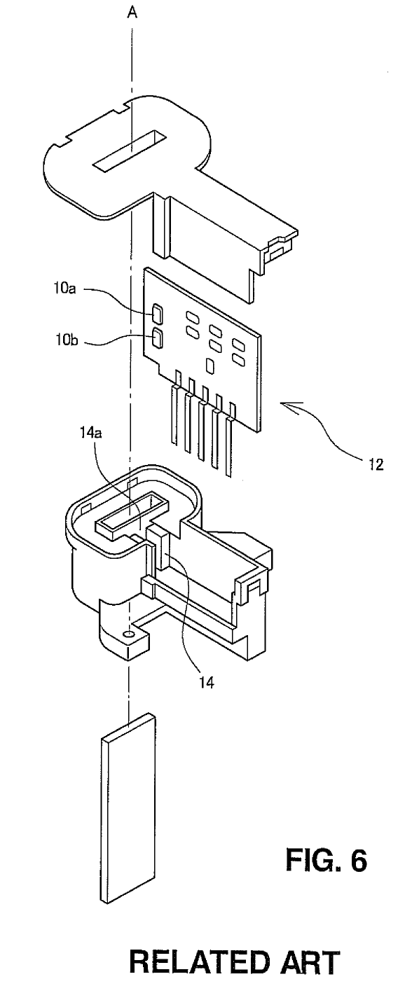

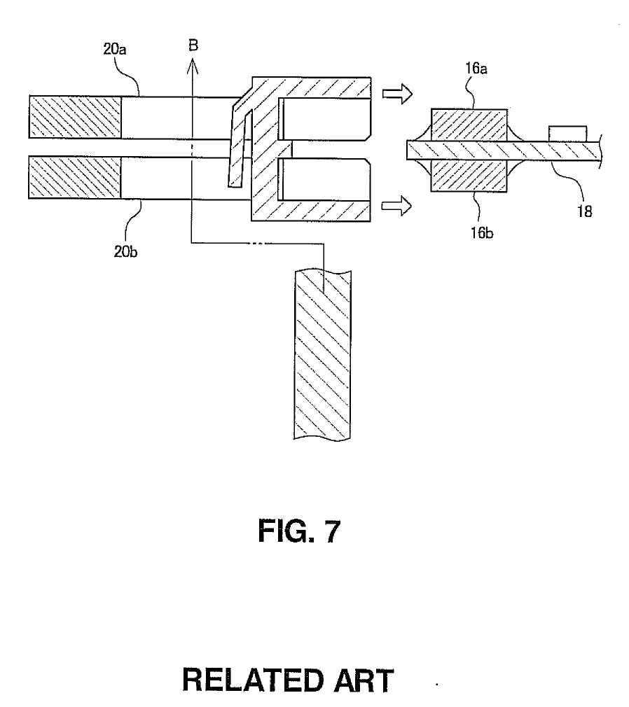

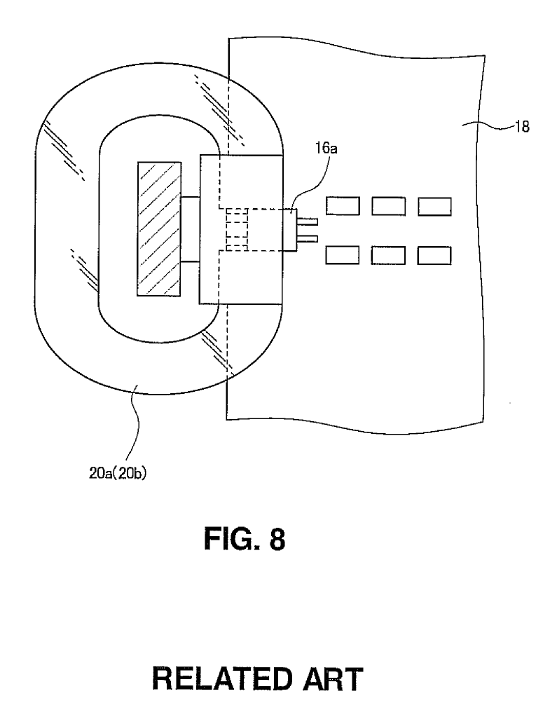

In the above-described preferred embodiment, a structure is employed in which the Hall elements 30a and 30b are placed opposing each other on both surfaces of the sensor board 32. Alternatively, as shown in an internal plan view of FIG. 5, a configuration may be employed in which Hall elements 30a and 30b having a flat plate shape are fixed on the sensor board 32 by a lead line 32d or the like, in a manner to oppose each other.

In this case, the opening 34a formed in the core 34 is preferably formed slightly larger than a sum of thicknesses of the Hall elements 30a and 30b and the opening formed therebetween.

With the configuration of the alternative embodiment also, the operation and advantage similar to those of the above-described preferred embodiment can be obtained.

What is claimed is:

1. A current detecting device comprising:
a plurality of Hall elements;
a board on which the Hall elements are surface-mounted; and
a core which surrounds a pass-through section through which a bus bar, through which a current to be detected flows, is passed, and which has, at a part of the core, an opening in which the Hall element is placed, wherein
the plurality of Hall elements are placed in series along a direction of a magnetic field line formed in the opening when a current flows through the bus bar.

2. The current detecting device according to claim 1, wherein
the plurality of Hall elements are mounted on both surfaces of the board.

3. The current detecting device according to claim 2, wherein
the plurality of Hall elements are mounted on both surfaces of the board, in a manner to oppose each other.

4. The current detecting device according to claim 1, wherein
the plurality of Hall elements are mounted on the board by a lead line which protrudes from the board.

5. The current detecting device according to claim 4, wherein
the plurality of Hall elements are mounted in a manner to oppose each other.
